(19) United States
(12) Patent Application Publication
(10) Pub. No.: US 2006/0138651 A1
(43) Pub. Date: Jun. 29, 2006

(54) Native incorporation of RF ID technology for the tracking of electronic circuitry

(75) Inventor: Joseph P. Walko, Jericho, VT (US)

Correspondence Address: Steven Fischman, Esq.;Scully, Scott, Murphy & Presser, 400 Garden City Plaza, Garden City, NY, 11530, US

(73) Assignee: INTERNATIONAL BUSINESS MACHINES CORPORATION, ARMONK, NY (US)

(21) Appl. No.: 11/024,321

(22) Filed: Dec. 28, 2004

(51) Int. Cl. H04B 7/00; H01L 21/50; H01L 23/34

(52) U.S. Cl. 257/728; 438/106; 455/41.2

(57) ABSTRACT

RF ID transmitter circuits are integrated into semiconductor chips during fabrication of the regular integrated circuits therein for providing identification capabilities for the semiconductor chips that comply with the IEEE family of standards 802. The RF ID transmitter circuit enables each chip to be identified in many different environments and at any of the stages after its fabrication, including inspection, distribution and commercial usage of the chip.

### BACKGROUND

1. Field of the Invention

The present invention relates generally to the manufacture of semiconductor wafers, chips and components, and more particularly pertains to a novel system and process for integrating RF ID transmitter circuits into semiconductor chips during their fabrication for providing identification capabilities for the semiconductor chips that comply with the IEEE family of standards 802. The RF ID transmitter circuit enables each chip to be identified in many different environments and at any of the stages after its fabrication, including inspection, distribution and commercial usage of the chip.

2. Description of the Prior Art

In the present state of the art, semiconductor chips and wafers are identified either by marking the container they are placed in (as in speed sort bins) or by physically marking each chip or wafer. These markings include both alphanumeric markings and bar codes. A major drawback of these identification methods is that they can place only a fairly small and limited amount of identifying information on each chip/wafer, and moreover an optical reading capability is required to access that limited amount of information.

U.S. Pat. No. 6,525,410 describes an integrated circuit (IC) device that includes an information unit that is electrically separate from the regular integrated circuit but is fabricated in the IC chip concurrently with the IC. The information unit includes a data bank, and electronic data is permanently encoded into the data bank. The overall emphasis of this patent is relatively narrow, and is on the detection and prevention of theft of the chips. Moreover, the integrated circuit device and information unit do not comply with the IEEE family of standards 802.

The IEEE family of standards 802 concern standards for local area networks (LANs) and metropolitan area networks (MANs) that enable stations to communicate directly on a point-to-point or point-to-multipoint basis without requiring them to communicate with any intermediate switching nodes. The basic communications capabilities provided by such LANs and WANs are packet-based, and the basic unit of transmission is a sequence of data octets, which can be any length within a range that is dependent upon the type of network. The IEEE family of standards 802 encompass the functionality of the lowest two layers of the OSI/RM (i.e. the physical layer and the data link layer). The IEEE family of standards 802 employ unique local area network media access control (LAN MAC) addresses, group addresses, and protocol identifiers. The IEEE can assign a unique Organizationally Unique Identifier (OUI) to an organization which is three octets (24 bits) in length, wherein the second least significant bit (LSB) is always a zero (0). The IEEE family of standards 802 also employ protocol identifiers that are five octets (40 bits) in length, with the first three octets of the protocol identifier consisting of an OUI. The LSB of the first octet of a protocol identifier is referred to as the M bit, and the X bit of a protocol identifier is the bit of the first octet adjacent to the M bit. All protocol identifiers derived from OUls assigned by the IEEE have the X bit (second least significant bit) set to zero (0) and are universally assigned.

It would be highly desirable to provide new chip ID capabilities for determining the presence and identity of chips within multi-chip packages, and for allowing an IP (information processing) search for chips with embedded RF IDs that enable the chips to be identified in many different environments and at any of the stages after their fabrication, including inspection, distribution and commercial usage of the chips.

### SUMMARY OF THE INVENTION

The present invention provides RF ID circuitry on each chip to be identified, and the RF ID circuitry is fabricated as an integral part of the manufacturing process for that chip. This provides a very low cost method of chip identification, reducing identification errors, and eliminating the need and associated expense for other forms of identification, and enabling new identification capabilities. The RF ID circuitry is fabricated in compliance with IEEE family of standards 802, such that the invention is useful for a very broad range of applications that are enabled because of compliance with the IEEE family of standards 802.

The present invention provides a semiconductor chip having an integrated circuit (IC) fabricated on a substrate along with RF ID (identification) circuitry fabricated on the substrate during fabrication of the IC, wherein a portion of the RF ID circuitry emits an RF signal that is used to identify the semiconductor chip when the chip is irradiated and scanned with an RF signal by standard RF ID scanning equipment. The RF ID circuitry complies with an IEEE family of standards 802 for local area networks (LANs) and metropolitan area networks (MANs), and includes a unique Organizationally Unique Identifier (OUI) to an organization which is three octets (24 bits) in length, wherein the second least significant bit (LSB) is always a zero (0).

Compliance with the IEEE family of standards 802 enables the present invention to have a much broader commercial and industrial utility than the narrow field of theft detection and prevention as disclosed by U.S. Pat. No. 6,525,410, and can be utilized to identify a chip in many different environments and at many different stages, from its initial fabrication through the manufacturers supply chain to the consumer, and even during usage by a consumer. Compliance with the IEEE family of standards 802 and Bluetooth technology enable the chip to be identified in many different environments and at any of the stages of its fabrication, inspection, distribution and commercial usage.

### BRIEF DESCRIPTION OF THE DRAWINGS

The foregoing objects and advantages of the present invention for native incorporation of RF ID technology for the tracking of electronic circuitry may be more readily understood by one skilled in the art with reference being had to the following detailed description of several embodiments thereof, taken in conjunction with the accompanying drawing in which:

FIG. 1 illustrates a logic flow diagram of the sequential steps involved in practicing the present invention for native incorporation of RF ID technology for the tracking of electronic circuitry.

### DETAILED DESCRIPTION OF THE INVENTION

Unlike current RF ID technologies that attach a stand-alone identification tag to the object to be identified, the present invention improves on this methodology and enables the chip industry to provide an RF ID capability integral to the product. This eliminates the possibility of mislabeling a chip later in the process, and is implemented by fabricating the RF ID circuit as an integral part of each chip.

The present invention provides a method of identifying wafers and chips by fabricating each of the wafers and chips with a standard range RF ID circuit or a near range RF ID circuit that is electrically powered by RF energy irradiating the circuit from RF ID scanning equipment, as is known in the art. The identification of wafers and chips by fabricating each of the wafers and chips with an RF ID pursuant to the present invention requires only standard RF ID scanning equipment. The in-situ or intrinsically fabricated RF ID allows identification and control of wafers at many different stages of processing, shipping and utilization of the wafer.

The RF ID circuitry on each chip is fabricated as an integral part of the manufacturing process of the regular integrated circuits on for that chip. This provides a very low cost method of chip identification, reducing identification errors, and enabling new identification capabilities.

The RF ID circuitry is fabricated in compliance with the IEEE family of standards 802, such that the invention is useful for a very broad range of applications that are enabled because of compliance with the IEEE family of standards 802, enabling each chip to be identified in many different environments and at any of the stages after its fabrication, including inspection, distribution and commercial usage of the chip.

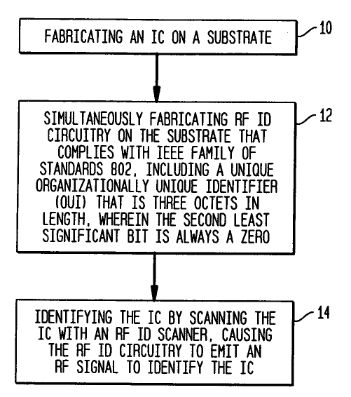

FIG. 1 illustrates a logic flow diagram of the sequential steps involved in practicing the method of the present invention for native incorporation of RF ID technology for the tracking of electronic circuitry. The method involves at 10 fabricating an integrated circuit (IC) on a substrate, and at 12 simultaneously fabricating RF ID (identification) circuitry on the substrate during fabrication of the IC. The RF ID circuitry emits an RF signal to identify the semiconductor chip, the RF ID circuitry complying with IEEE family of standards 802 for local area networks (LANs) and metropolitan area networks (MANs) and including a unique Organizationally Unique Identifier (OUI) to an organization which is three octets (24 bits) in length, wherein the second least significant bit (LSB) is always a zero (0). At 14, the IC is identified by scanning the IC with an RF IC scanner, causing the RF ID circuitry to emit an RF signal to identify the IC.

The present invention provides new chip ID capabilities for determining the presence and identity of chips within multi-chip packages. The present invention also allows an IP (information processing) search for chips with embedded RF IDs that enable the chips to be identified in many different environments and at any of the stages after their fabrication, including inspection, distribution and commercial usage of the chips.

Scribing of some chips may still be necessary, such as to provide for manual identification of the chips.

While several embodiments and variations of the present invention for a native incorporation of RF ID technology for the tracking of electronic circuitry are described in detail t should be apparent that the disclosure and teachings of the present invention will many alternative designs to those skilled in the art.

Having thus described our invention, what we claim as new and desire to secure by Letters Patent is:

1. A semiconductor chip comprising:
an integrated circuit (IC) fabricated on a substrate; and
RF ID (identification) circuitry fabricated on said substrate during fabrication of the IC, wherein a portion of said RF ID circuitry emits an RF signal to identify said semiconductor chip, said RF ID circuitry complying with an IEEE family of standards 802 for local area networks (LANs) and metropolitan area networks (MANs).

2. The semiconductor chip of claim 1, wherein said RF ID circuitry complies with the IEEE family of standards 802 and employs unique local area network media access control (LAN MAC) addresses, group addresses, and protocol identifiers.

3. The semiconductor chip of claim 2, wherein said RF ID circuitry complies with the IEEE family of standards 802 and includes a unique Organizationally Unique Identifier (OUI) to an organization.

4. The semiconductor chip of claim 3, wherein said RF ID circuitry complies with the IEEE family of standards 802 and employs protocol identifiers that are five octets (40 bits) in length, with the first three octets of the protocol identifier consisting of said OUI.

5. The semiconductor chip of claim 4, wherein said OUI is three octets (24 bits) in length, wherein the second least significant bit (LSB) is always a zero (0).

6. The semiconductor chip of claim 5, wherein the semiconductor chip is packaged in a multi-chip package.

7. The semiconductor chip of claim 1, wherein said RF ID circuitry complies with the IEEE family of standards 802 and includes a unique Organizationally Unique Identifier (OUI) to an organization.

8. The semiconductor chip of claim 1, wherein said RF ID circuitry complies with the IEEE family of standards 802 and employs protocol identifiers that are five octets (40 bits) in length, with the first three octets of the protocol identifier consisting of an OUI.

9. The semiconductor chip of claim 1, wherein said RF ID circuitry complies with the IEEE family of standards 802 and includes a unique Organizationally Unique Identifier (OUI) to an organization that is three octets (24 bits) in length, wherein the second least significant bit (LSB) is always a zero (0).

10. The semiconductor chip of claim 1, wherein the semiconductor chip is packaged in a multi-chip package.

11. A method of fabricating a semiconductor chip comprising:
fabricating an integrated circuit (IC) on a substrate; and
simultaneously fabricating RF ID (identification) circuitry on said substrate during fabrication of the IC, wherein a portion of said RF ID circuitry emits an RF signal to identify said semiconductor chip, said RF ID circuitry complying with an IEEE family of standards 802 for local area networks (LANs) and metropolitan area networks (MANs) and including a unique Organizationally Unique Identifier (OUI) to an organization which is three octets (24 bits) in length, wherein the second least significant bit (LSB) is always a zero (0).

12. The method of claim 11, including packaging the semiconductor chip in a multi-chip package.

13. A method of identifying a semiconductor chip comprising:
fabricating the semiconductor chip with an integrated circuit (IC) and RF ID (identification) circuitry, wherein a portion of said RF ID circuitry emits an RF signal to identify said semiconductor chip, said RF ID circuitry complying with an IEEE family of standards 802 for local area networks (LANs) and metropolitan area networks (MANs) and including a unique Organizationally Unique Identifier (OUI) to an organization which is three octets (24 bits) in length, wherein the second least significant bit (LSB) is always a zero (0).

14. The method of claim 13, including utilizing the RF ID circuitry for determining the presence and identity of chips within a multi-chip package.

15. The method of claim 13, including performing an information processing (IP) search for chips with embedded RF IDs at any of the stages after their fabrication, including inspection, distribution and commercial usage of the chips.

16. The method of claim 13, wherein RF ID scanning equipment irradiates and scans the chip with an RF signal causing the RF ID circuitry to emit an RF signal that is used to identify the semiconductor chip.
